(19) United States
(12) Patent Application Publication
(10) Pub. No.: US 2012/0242360 A1
(43) Pub. Date: Sep. 27, 2012

(54) High-frequency coupling testing device by coupling effect

(76) Inventors: Keng-Yi Huang, Hsinchu Hsiang (TW); Chao-Ping Hsieh, Hsinchu Hsiang (TW); Wei-Cheng Ku, Hsinchu Hsiang (TW); Chih-Hao Ho, Hsinchu Hsiang (TW)

(21) Appl. No.: 13/425,410

(22) Filed: Mar. 20, 2012

(30) Foreign Application Priority Data
Mar. 22, 2011 (TW) 100109785

(51) Int. Cl. G01R 31/20; H01P 1/20

(52) U.S. Cl. 324/754.03; 333/202

(57) ABSTRACT

Method for transmitting a high-frequency signal by a coupling effect includes receiving a high-frequency signal by a high-frequency circuit and coupling the high-frequency signal to a coupling circuit by the coupling effect to output a high-frequency coupled signal, and adjusting a filter between the coupling circuit and the high-frequency circuit formed by the coupling effect for adjusting transmission frequency of the high-frequency coupled signal; upon when the high-frequency circuit includes a high-frequency metal probe, the coupling circuit comprises a coupling transmission wire. Meanwhile, upon when the high-frequency circuit includes the coupling transmission wire, the coupling circuit includes the high-frequency metal probe. Further, the filter between the coupling circuit and the high-frequency circuit can be adjusted by changing the number of the coupling metal probes surrounding the high-frequency metal probe, or by changing the distances between the coupling metal probes and the high-frequency metal probes.

### FIELD OF THE INVENTION

The present invention relates to a high-frequency testing system for semiconductor manufacture, and more particularly, to a testing device for transmitting high-frequency testing signals by coupling effect and a method for adjusting the filter formed by the coupling effect.

### BACKGROUND OF THE INVENTION

In semiconductor manufacture for automatic wafer-level testing, a tester is used to transmit testing signals to a device under test (DUT), e.g. an integrated circuit (IC), and to read the testing result from the DUT. However, since the distances between the testing pads of the DUT are relatively small to the tester, a probe card is required to be disposed between the testing pads of the DUT and the tester for space transforming. In this way, the testing signals from the tester can be transmitted to the testing pads of the DUT through the circuits and probes of the probe card, and the testing result from the DUT can be transmitted back to the tester through the probes and the circuits of the probe card for the tester to determine if the DUT has failed or not.

For those DUTs of high-speed/high-frequency operation, the layout of the circuit and the probes of the probe card have to be designed specifically for the requirement of impedance matching on the transmission paths for the high-frequency signals because the high-frequency signals are highly sensitive to the transmission environment. However, if the impedance of each component in the probe card does not exactly match to each other, signal reflection loss at the conjunctions between each component then occurs, which thereby deteriorates the reliability of the probe card.

Thus, the probe card for the high-speed operation is then improved to connect the DUT by use of coupling effect, which means the probe card does not physically contact the DUT. Instead, those testing signals between the probe card and the DUT are transmitted by the coupling effect between the probes of the probe card and the testing pads of the DUT. For example, US patent publication No. 20070296435 discloses “AC coupled parametric test probe”. By using insulating material at the tips of the probes to form specific coupling capacitors, and changing distances between the probes and the DUT to adjust the sizes of the coupling capacitors, the transmission paths provided by the AC coupled parametric test probe can be employed for high-frequency signals. However, such design has some drawbacks: 1. by using the insulating material at the tips of the probes to form the coupling capacitors, the quality of the coupled signals is deteriorated when the insulating material is worn out or covered by some other unexpected particles; 2. by changing distances between the probes and the DUT to adjust the coupling capacitors, the distance parameters will be changed when the elasticity of the probe is decreased. Those drawbacks also deteriorate the reliability of the probe card.

From the above explanation, it can be understood that most of the conventional probe cards can hardly maintain impedances of their components matching to each other, as required by high-frequency transmission because of the reliability issues of their fabrications or the physical characteristic of the material used, which is undesirable.

### SUMMARY OF THE INVENTION

It is therefore one of the objectives of the present invention to provide a method for transmitting a high-frequency signal by coupling effect and a plurality of related testing devices for a device under test (DUT) of high-frequency operation with high transmission quality.

In order to achieve the above mentioned goal, a method for transmitting a high-frequency signal by a coupling effect is provided. The method may comprise receiving a plurality of high-frequency signals by a high-frequency circuit and coupling the high-frequency signals to a coupling circuit by means of the coupling effect to output a high-frequency coupled signal, forming one of the high-frequency circuit or the coupling circuit comprising a high-frequency metal probe and forming one of the high-frequency circuit or the coupling circuit comprising a coupling transmission wire, respectively, and adjusting a filter between the coupling circuit and the high-frequency circuit formed by the coupling effect for adjusting a transmission frequency of the high-frequency coupled signal. When the high-frequency circuit comprises the high-frequency metal probe, the coupling circuit comprises the coupling transmission wire, and when the high-frequency circuit comprises the coupling transmission wire, the coupling circuit comprises the high-frequency metal probe.

According to another embodiment of the present invention, a high-frequency coupling testing device for testing a device under test (DUT) by a coupling effect is provided. The high-frequency coupling testing device may comprise a circuit substrate, a probe base, a high-frequency metal probe passing through the probe base for contacting the DUT, and a first coupling metal probe passing through the probe base for electrically connecting the coupling transmission wire. The circuit substrate may comprise a coupling transmission wire for electrically connecting a tester. The first coupling metal probe may be configured adjacent to the high-frequency metal probe to form a filter by the coupling effect. When the tester transmits a testing signal to the coupling transmission wire, the testing signal is filtered by the filter to form a high-frequency coupled signal and the high-frequency coupled signal is outputted from the high-frequency metal probe to the DUT for testing.

According to another embodiment of the present invention, a high-frequency coupling testing device for testing a DUT by a coupling effect is provided. The high-frequency coupling testing device may comprise a circuit substrate, a high-frequency transmission wire, a coupling transmission wire, and a high-frequency metal probe for electrically connecting the high-frequency transmission wire and the DUT. The circuit substrate may comprise an upper surface, a lower surface, and an electrical contact on the upper surface for electrically connecting a tester. The coupling transmission wire may be configured adjacent to the high-frequency transmission wire for forming a filter by the coupling effect. The coupling transmission wire may electrically connect the electrical contact, and when the tester transmits a testing signal to the coupling transmission wire, the testing signal may be filtered by the filter to form a high-frequency coupled signal and the high-frequency coupled signal may be outputted from the high-frequency metal probe to the DUT for testing.

Therefore, by adopting the embodiments of the present invention, the impedances within the transmission paths for the high-frequency signals will match to each other and the testing devices of the embodiments of present invention can be adjusted for the DUT of different frequencies.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a high-frequency coupling testing device according to a first embodiment of the present invention.

FIG. 2 is a diagram illustrating a high-frequency coupling testing device according to a second embodiment of the present invention.

FIG. 3 is a diagram illustrating the electrical connection relationship between the adjusting component and the coupling transmission wire according to the second embodiment of the present invention.

FIG. 4 is a diagram illustrating a high-frequency coupling testing device according to a third embodiment of the present invention.

FIG. 5 is a diagram illustrating a high-frequency coupling testing device according to a fourth embodiment of the present invention.

FIG. 6 is a diagram illustrating a high-frequency coupling testing device according to a fifth embodiment of the present invention.

FIG. 7 is a diagram illustrating a high-frequency coupling testing device according to a sixth embodiment of the present invention.

### DETAILED DESCRIPTION OF THE INVENTION

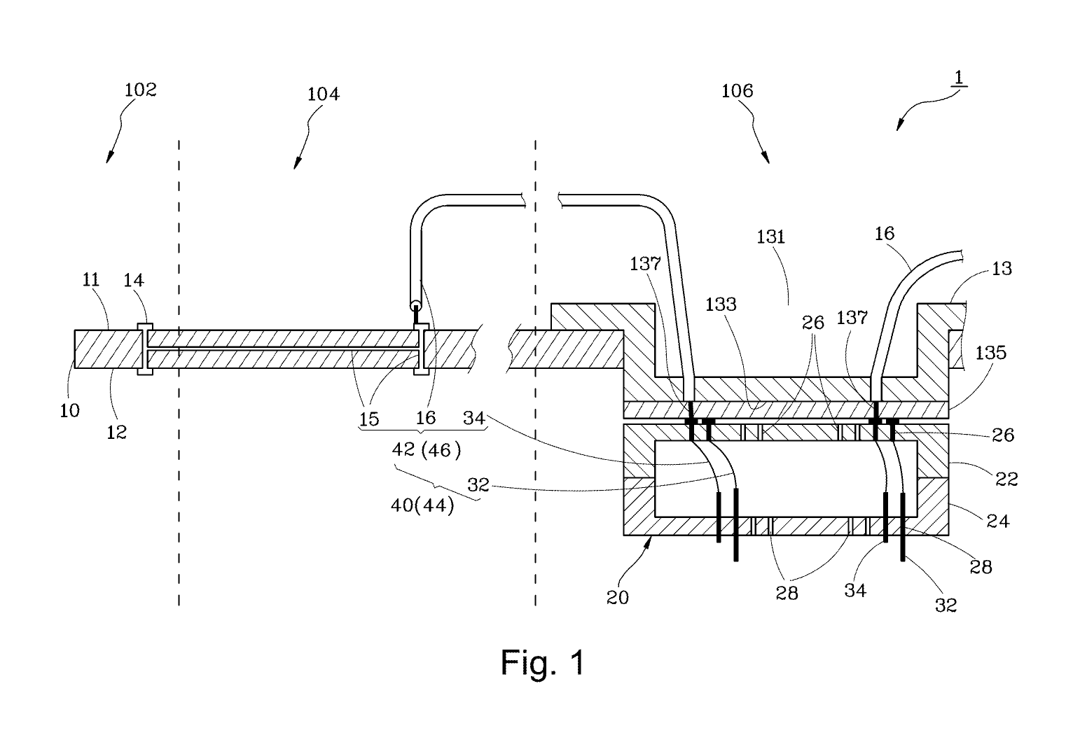

FIG. 1 shows a high-frequency coupling testing device 1 according to a first embodiment of the present invention. The testing device 1 is disposed between a tester (not shown) and a DUT of high-frequency operation (not shown) for testing. More particularly, the testing device 1 forms a filter by coupling effect so that the tester can connect the DUT through the filter, and the noises in the signals transmitted between the tester and the DUT can then be filtered out. In the present invention, the vertical probe configured of high density array should be considered as a non-limiting example, which means that the probe employed in the present invention can be replaced by other kinds of probes, e.g. a cantilever probe, or a MEMS probe. The testing device 1, from periphery to center, is divided into three parts: a testing area 102, a transferring area 104, and a probe area 106. When the tester transmits a testing signal to the DUT through the testing device 1, the tester acts as a signal transmitting end and the DUT acts as a signal receiving end. In such situation, the testing signal from the signal transmitting end is transmitted to the testing area 102 first, then transmitted to the vertical probe of the probe area 106 through the transferring area 104, and is outputted to the signal receiving end. After that, the DUT generates a testing result according to the received testing signal, and outputs the testing result through the signal output pad to the testing device 1, which means that the DUT acts as a signal transmitting end and the tester acts as a signal receiving end. In such situation, the testing result is transmitted through the probe area 106 first, then through the transferring area 104 and the testing area 102, and finally is received by the signal receiving end. Then the tester analyzes the testing result for determining whether if the DUT has failed or not.

The testing device 1 comprises a circuit substrate 10, a probe base 20, a plurality of high-frequency metal probes 32, and a plurality of coupling metal probes 34. The circuit substrate 10 comprises an upper surface 11 and a lower surface 12, a locating base 13, a plurality of electrical contacts 14 on the upper surface 11 for electrically connecting the tester, a plurality of conductive wires 15 and a plurality of coupling transmission wires 16. The locating base 13 is disposed in the probe area 106, and more particularly, in the center of the circuit substrate 10, for installing the probe base 20. In the present embodiment, the circuit substrate 10 can be made of a generic circuit substrate, and each conductive wire 15 electrically connects a corresponding electrical contact 14 of the testing area 102 to a corresponding coupling transmission wire 16 on the upper surface 11 of the transferring area 104. In this way, the electrical contact 14 can electrically conduct to any specific position of the probe area 106 by changing the position of the corresponding coupling transmission wire 16. The locating base 13 comprises a concave trough 131 and a convex surface 133, and an insulating plate 135. The insulating plate 135 is made of insulating material; and the upper surface of the insulating plate 135 is attached to the convex surface 133. The coupling transmission wire 16 is coupled to the convex surface 133 through the concave trough 131 and the metal core of the coupling transmission wire 16 is further coupled to the pad 137 disposed on the lower surface of the insulating plate 135 (opposite to the upper surface of the insulating plate 135).

The probe base 20 is disposed at the bottom of the insulating plate 135, and comprises an upper die 22, a lower die 24, and a plurality of holes 26 and 28. The upper and lower dies 22 and 24 are made of insulating material, and the peripheries of the dies 22 and 24 are combined to each other. The holes 26 and 28 are disposed for the high-frequency metal probes 32 and the coupling metal probes 34 to vertically pass through the probe bases 20, which means that the metal probes 32 and 34 are arranged vertically to the circuit substrate 10. Each of the metal probes 32 and 34 has an elastic part between the dies 22 and 24 acting as a buffer for the probe base 20 to resist vertical impacts.

One end of each high-frequency metal probe 32 protrudes from the top of the upper die 22 to abut against the insulating plate 135, and the other end of each high-frequency metal probe 32 protrudes from one corresponding hole 28 of the lower die 24 to contact the DUT. One end of each coupling metal probe 34 protrudes from the top of the upper die 22 to contact one corresponding pad 137 at the bottom of the insulating plate 135 for electrically connecting to one corresponding coupling transmission wire 16, and the other end of each coupling metal probe 34 is fixed by one corresponding hole 28 of the lower die 24. Each coupling metal probe 34 is disposed adjacent to one corresponding high-frequency metal probe 32 as a pair, so that coupling effect occurs between the one high-frequency metal probe 32 and its corresponding coupling metal probe 34. In other words, capacitive/inductive coupling between the high-frequency metal probe 32 and the coupling metal probe 34 is formed by the coupling effect therebetween and can be seen or regarded as a high-pass filter or a band-pass filter. That is, a signal, which passes from the high-frequency metal probe 32 to the coupling metal probe 34, must have the same frequency as the formed high-pass/band-pass filter dictates. By changing the distance between the coupling metal probe 34 and the corresponding high-frequency metal probe 32, e.g. changing the positions of the holes 26 and 28, the filtering frequency of the formed high-pass filter or band-pass filter can be adjusted to specific frequency bands. In this way, the DC power loss between the high-frequency metal probes 32 and the tester can be reduced and the noises on unwanted frequency can be reduced as well. Therefore, the positions of the holes 26 and 28 have to be predetermined for the formed high-pass filter/band-pass filter to meet the required frequency bands. In fact, the coupling metal probe 34 is only used to form the capacitive/inductive coupling for high-frequency signals and do not contact the corresponding high-frequency metal probe 32. In other words, the tip of the coupling metal probe 34 can abut against the lower die 24, or be fixed in the hole 28, or, as described in the present embodiment, protrude from the lower die 24.

However, if the cantilever probe or the MEMS probe is employed instead of the vertical probe in the present embodiment, the probe base, the high-frequency probes, and the coupling metal probes will be thereby modified accordingly, but the DUT is still only contacted by the high-frequency metal probe, and the coupling metal probe is still only electrically connected to the coupling transmission wire. Besides, by changing the distances between the coupling metal probes and the high-frequency metal probes, the frequency of the formed filter can be adjusted as well.

When the tester transmits the testing signal to the DUT, the transmission path of the testing signal is as follow, in this order: the electrical contact 14, the conductive wire 15, the coupling transmission wire 16, the coupling metal probe 34, the high-frequency metal probe 32, and the signal input pads of the DUT. In other words, the testing signal of the tester is received by the electrical contact 14 of the circuit substrate 10, and is then transmitted to the coupling metal probe 34 through the conductive wire 15 and the coupling transmission wire 16. Then, the testing signal is filtered to form the high-frequency coupled signal when passing through the high-pass/band-pass filters formed between the metal probes 32 and 34, and the high-frequency coupled signal is outputted from the high-frequency metal probe 32 to the signal input pads of the DUT. Such transmission path described above forms a high-frequency coupling circuit 40 of the testing device 1, and the conductive wire 15, the coupling transmission wire 16, and the coupling metal probe 34 forms the high-frequency circuit 42 of the high-frequency coupling circuit 40.

When the DUT transmits the corresponding testing result to the tester, the transmission path of the testing result is as follow, in this order: the signal output pad of the DUT, the high-frequency metal probe 32, the coupling metal probe 34, the coupling transmission wire 16, and the conductive wire 15. In other words, the testing result of the DUT is outputted from the signal output pad of the DUT to the high-frequency metal probe 32. Then, the testing result is filtered to form the high-frequency coupled signal when passing through the high-pass/band-pass filters formed between the metal probes 32 and 34, and the high-frequency coupled signal is outputted from the coupling metal probe 32 to the tester through the coupling transmission wire 16 and the conductive wire 15. Such transmission path described above forms a high-frequency coupling circuit 44 of the testing device 1; the high-frequency metal probe 32 form a high-frequency circuit of the high-frequency coupling circuit 44, and the coupling metal probe 34, the coupling transmission wire 16, and the conductive wire 15 form the coupling circuit 46 of the high-frequency coupling circuit 44.

From the above description, it can be understood that the testing device of the present invention utilizes the high-frequency circuit for receiving the high-frequency signals from the signal transmitting end, and utilizes the coupling circuit for outputting the high-frequency coupled signal to the signal receiving end. Furthermore, between the high-frequency circuit and the coupling circuit, the present invention provides capacitive/inductive coupling formed between the high-frequency metal probe 32 and the coupling metal probe 34. Therefore, by adjusting the amount of capacitive/inductive coupling between the coupling circuit and the high-frequency circuit, the requirement for the high-frequency transmission of the DUT can be met and the impedances on the entire transmission path can be matched consistently so that the signal reflection loss is effectively reduced on the transmission path, and the transmission quality is thereby improved.

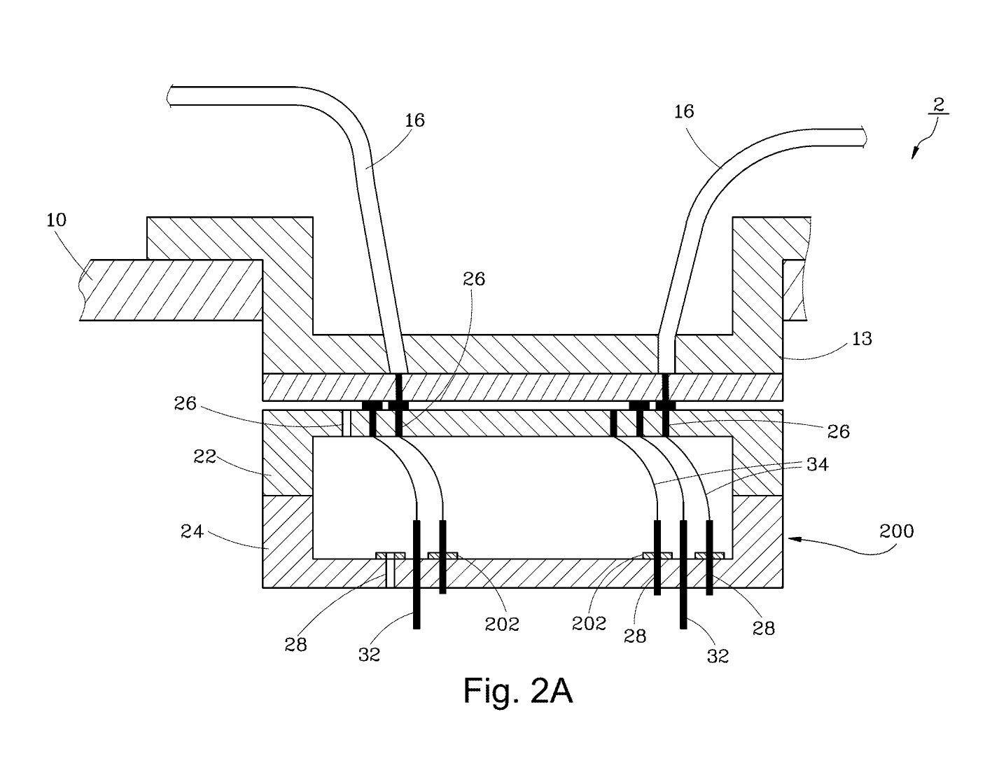

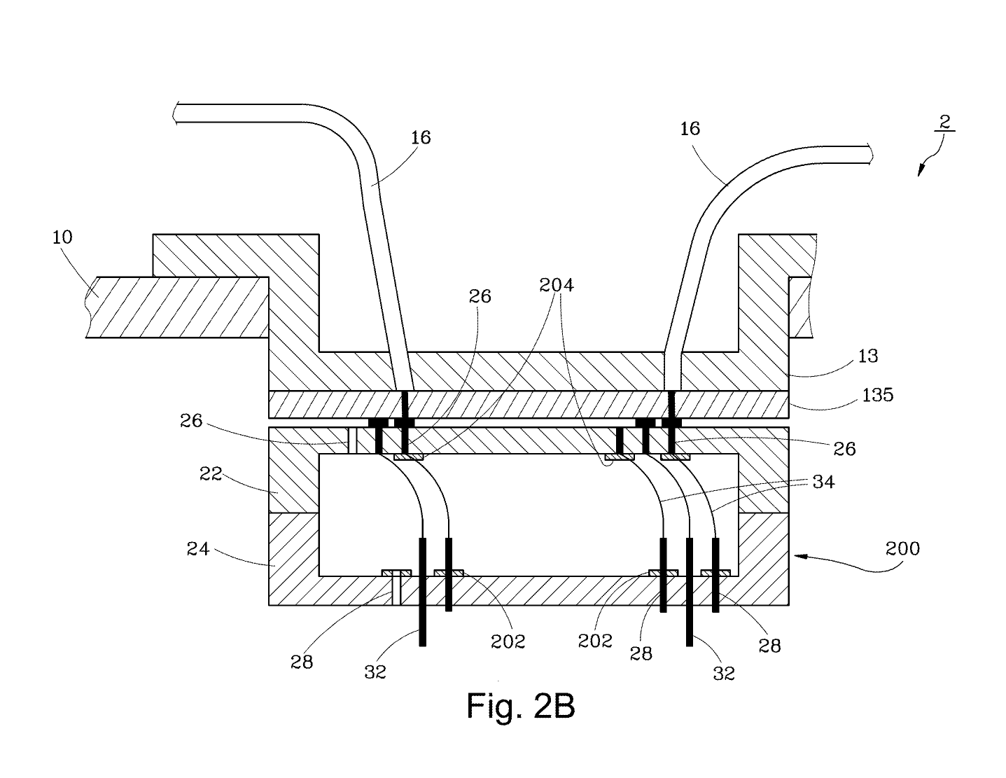

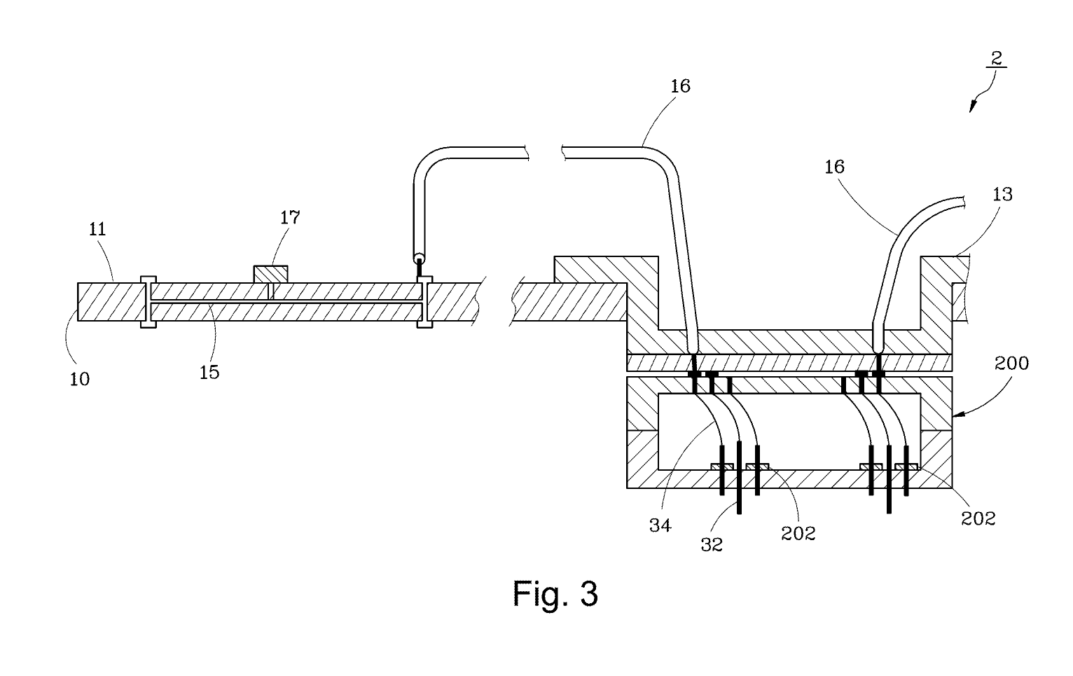

It is noticeable that the capacitive/inductive coupling between the high-frequency metal probe 32 and the coupling metal probe 34 can be adjusted not only by changing the positions of the holes 26 and 28 of the probe base 20, but also by the method as described by the testing device 2 according to the second embodiment of the present invention, as shown in FIG. 2 and FIG. 3. Different from the first embodiment described above, the probe base 200 further comprises a plurality of rounded conductive layers 202 on the lower die 24, as shown in FIG. 2A. Each conductive layer 202 is disposed on one corresponding hole 28 adjacent to one corresponding high-frequency metal probe 32 to surround the corresponding high-frequency metal probe 32. By such disposition, those coupling metal probes 34 surrounding the corresponding high-frequency metal probe 32 are short-circuited to each other through the conductive layer 202. In this way, only one of those coupling metal probes 34 is needed to electrically connect to the coupling transmission wire 16 so as to form the equivalent capacitive/inductive coupling to the corresponding high-frequency metal probe 32 from those coupling metal probes 34. Therefore, the testing device 2 can adjust the capacitive/inductive coupling between the coupling circuit and the high-frequency circuit by changing the number of the coupling metal probes 34 surrounding the high-frequency metal probe 32. The number of the coupling metal probes 34 surrounding the corresponding high-frequency metal probe 32 can be changed simply by inserting/removing the coupling metal probes 34 from the holes 26 of the upper die 22 and the holes 28 of the lower die 24. The position of the conductive layer 202 for short-circuiting the coupling metal probes 34 is not limited to be configured on the lower die 24 of the probe base 20, and can be any position that contacts the coupling metal probes 34, e.g. the insulating plate 135 of the circuit substrate 10, or the upper die 22 and/or the lower die 24 of the probe base 20, as the conductive layers 202 and 204 shown in FIG. 2B. The additional conductive layers 202 on the upper die 22 further improve the quality of high-frequency transmission.

Please refer to FIG. 3. The testing device 2 further comprises an adjusting component 17 for slightly adjusting the transmission frequency of the high-frequency coupled signals. The adjusting component 17 is disposed on the upper surface 11 of the circuit substrate 10 and can be a capacitor and/or an inductor, which electrically connects the conductive wire 15 or the coupling transmission wire 16. Thus, by adjusting capacitance/inductance provided by the adjusting component 17, the transmission frequency of the high-frequency coupled signal can be further adjusted.

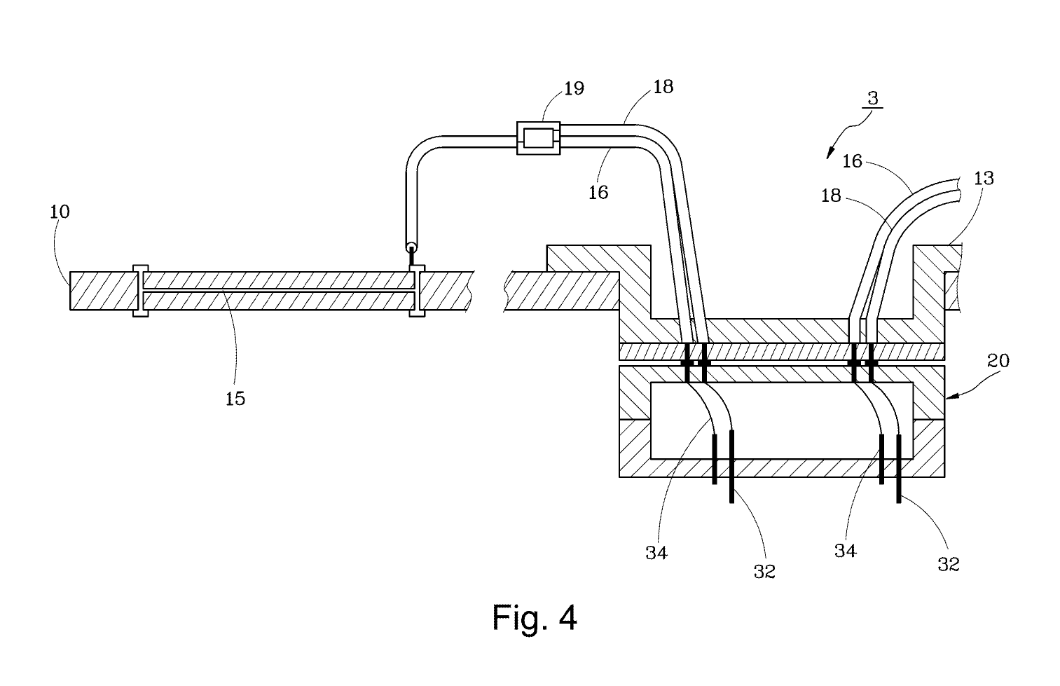

Please refer to FIG. 4. FIG. 4 shows a testing device 3 according to a third embodiment of the present invention. The testing device 3 further comprises a high-frequency transmission wire 18, which electrically connects to the high-frequency metal probe 32. The high-frequency transmission wire 18 is disposed along the coupling transmission wire 16 and is configured adjacent to the coupling transmission wire 16. Different from adjusting distance between the high-frequency metal probe 32 and the coupling metal probe 34 or changing the number of the coupling metal probes 34 to adjust the transmission frequency of the high-frequency coupled signal, the testing device 3 adjusts the transmission frequency of the high-frequency coupled signal by changing the length of the high-frequency transmission wire 18 or changing the distance between the high-frequency transmission wire 18 and the coupling transmission wire 16 to adjust capacitance/inductance between the coupling circuit and the high-frequency circuit. Besides, the testing device 3 further comprises an adjusting component 19 for slightly adjusting the transmission frequency of the high-frequency coupled signal. The adjusting component 19 can be a capacitor and/or an inductor, which electrically connects the high-frequency transmission wire 18 and the coupling transmission wire 16. Thus, by adjusting capacitance/inductance provided by the adjusting component 19, the transmission frequency of the high-frequency coupled signal can be further adjusted.

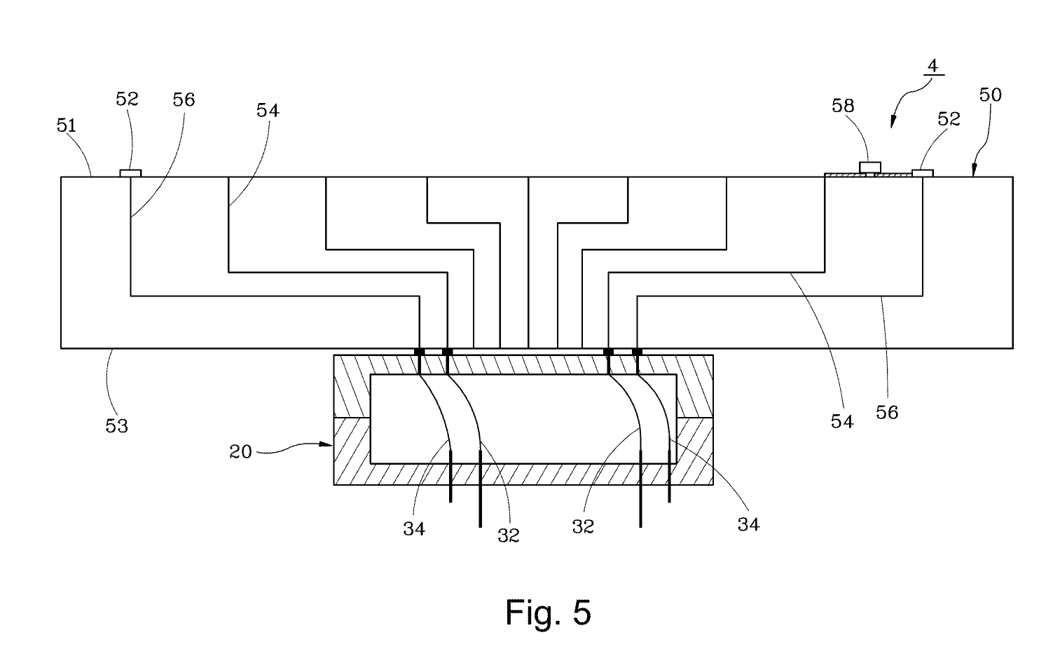

Moreover, the disposition of the coupling transmission wire 16 and the high-frequency transmission wire 18 is not limited to those embodiments described above, and can be different in other embodiments. FIG. 5 shows a testing device 4 according to a fourth embodiment of the present invention. The testing device 4 comprises a circuit substrate 50, the probe base 20, the high-frequency metal probes 32, and the coupling metal probes 34, as provided in the first embodiment of the present invention. The circuit substrate 50 is customized with certain circuit structure, and is different from the first embodiment of the present invention. An upper surface 51 of the circuit substrate 50 is disposed with a plurality of electrical contacts 52 for electrically connecting the tester, a lower surface 53 is disposed with the probe base 20, and in the circuit substrate 50, a plurality of high-frequency transmission wires 54 and a plurality of coupling transmission wires 56 are disposed to electrically connect the high-frequency metal probes 32 and the coupling metal probes 34 on the lower surface 53, respectively. The coupling transmission wire 56 electrically connects the electrical contact 52 on the upper surface 51. Therefore, the layout of the circuit substrate 50 for the high-frequency transmission wire 54 and the coupling transmission wire 56 determines the transmission frequency of the high-frequency coupled signal of the testing device 4, and by adjusting the distance between the high-frequency transmission wire 54 and the coupling transmission wire 56, the transmission frequency of the high-frequency coupled signal can be adjusted as required. For the testing device 4 of the fourth embodiment of the present invention to be applied to DUT of different specifications, the upper surface 51 of the circuit substrate 50 comprises an adjusting component 58. The adjusting component 58 can be a capacitor and/or an inductor, which electrically connects the high-frequency transmission wire 54 and the coupling transmission wire 56. Thus, by adjusting capacitance/inductance provided by the adjusting component 58, the capacitive/inductive coupling between the coupling circuit and the high-frequency circuit can be adjusted, and the transmission frequency of the high-frequency coupled signal can be further adjusted. Additionally, since the adjusting component 58 is only disposed for adjusting the impedances on the signal transmission paths, the electrical connections between the adjusting component 58, the coupling transmission wire 56, and the high-frequency transmission wire 54 can be different. For example, the adjusting component 58 can electrically connect the coupling transmission wire 56 to ground, or electrically connect the high-frequency transmission wire 54 to ground.

The probe base 20 in FIG. 5 can be replaced by the probe base 200 of the second embodiment for electrically connecting the coupling metal probes 34 to the coupling transmission wires 56 if each high-frequency transmission wire 54 is surrounded by multiple number of coupling transmission wires 56. In this way, the capacitive/inductive coupling between the coupling circuit and the high-frequency circuit can be adjusted by inserting/removing the coupling metal probes 34 from the probe base 20.

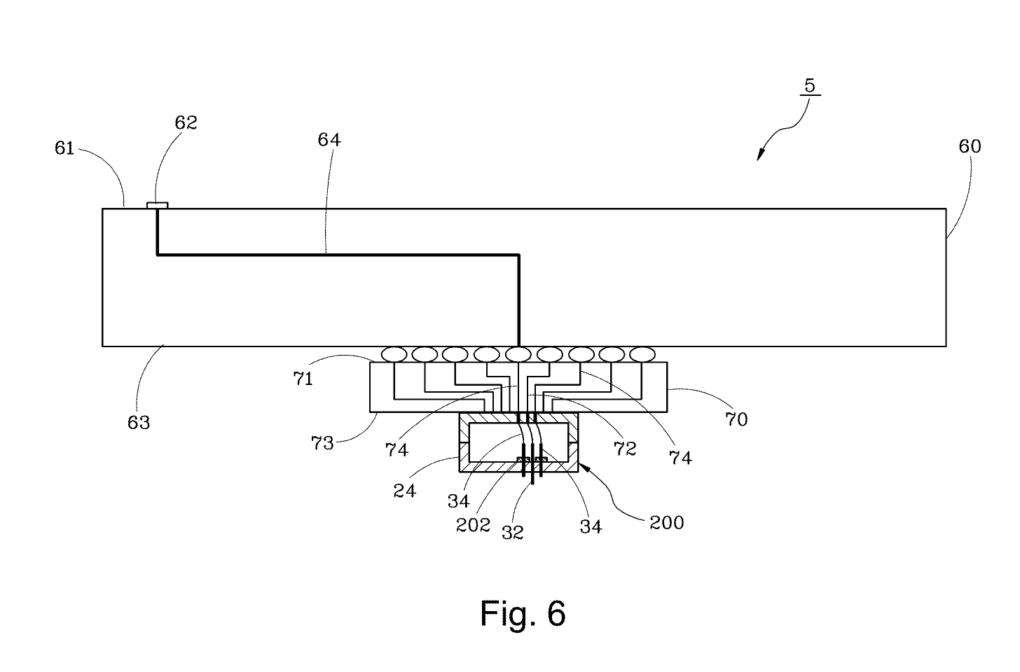

Alternatively, the customized circuit substrate 50 can be replaced by a generic circuit substrate and a space transformer, as a testing device 5 shown in FIG. 6 according to a fifth embodiment of the present invention. The testing device 5 comprises a circuit substrate 60, a space transformer 70, a probe base 200, the high-frequency metal probes 32, and the coupling metal probes 34 as described in the second embodiment of the present invention. The circuit substrate 60 comprises a plurality of electrical contacts 62 on the upper surface 61 for electrically connecting to the tester and a plurality of first coupling transmission wires 64 between the upper surface 61 and the lower surface 63.

The circuit substrate 60 is electrically connected to a top side 71 of the space transformer 70. The probe base 200 and high-frequency metal probes 32 and the coupling metal probes 34 are disposed against a bottom side 73 of the space transformer 70. A plurality of high-frequency transmission wires 72 and a plurality of second coupling transmission wires 74 are disposed in the space transformer 70. Each second coupling transmission wire 74 is adjacent to one corresponding high-frequency transmission wire 72 and electrically connects one corresponding coupling metal probe 34. Each high-frequency transmission wire 72 electrically connects one corresponding high-frequency metal probe 32.

According to the description for the second embodiment of the present invention, since the coupling metal probes 34 surrounding a corresponding high-frequency metal probe 32 are short-circuited by the conductive layers 202 or 204, those second coupling transmission wires 74 electrically connecting to the coupling metal probes 34 are short-circuited as well, which means that only one of those second coupling transmission wires 74 is needed to electrically connect to the first coupling transmission wire 64 of the circuit substrate 60. In this way, besides adjusting the capacitive/inductive coupling between the coupling circuit and the high-frequency circuit by changing the number of the inserted coupling metal probes 34, the testing device 5 improves the accuracy of the adjustment of the transmission frequency of the high-frequency coupled signal by using the high-frequency transmission wire 72 and the second coupling transmission wire 74 of the space transformer 70, which means the second coupling transmission configured adjacent to the corresponding high-frequency transmission wire also provides adjusting function for the filter between the coupling circuit and the high-frequency circuit, so as to eliminate the adjusting component as described in the above embodiments.

In the testing device 5 of the present embodiment, it is noticeable that the area of the capacitive/inductive coupling comprises not only the area between the high-frequency metal probe 32 and the coupling metal probe 34, but also the area of the space transformer 70 as well. Besides, the area of the capacitive/inductive coupling can further comprise the area of the circuit substrate 60 if the circuit substrate 60 is modified to be that of similar structure as the circuit substrate 50 provided by the fourth embodiment of the present invention. In this way, the testing device 5 can add any adjusting component on the circuit substrate 60 for changing the transmission frequency of the high-frequency coupled signal and the impedances on the transmission path.

Additionally, the space transformer 70 can also be adapted between the circuit substrate and the probe base of other embodiments of the present invention. For example, the space transformer 70 can be disposed between the circuit substrate 10 and the probe base 20 of the first embodiment of the present invention. If so, the size of the probe area 106 on the circuit substrate 10 does not have to match the size of the probe base 20, which provides the circuit substrate 10 more flexibility.

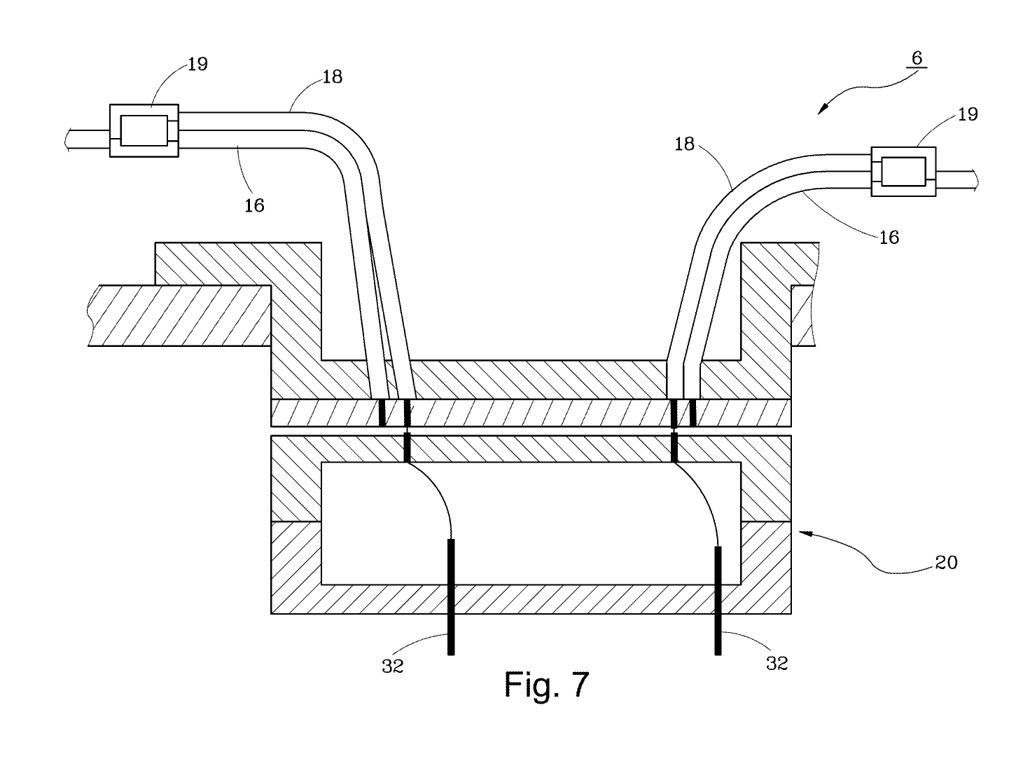

Furthermore, since the present invention mainly provides adjustment of the capacitive/inductive coupling between the coupling circuit and the high-frequency circuit, the coupling effect occurs between the high-frequency transmission wires 18 or 54 and their corresponding coupling transmission wires, as described in the third and fourth embodiments of the present invention (FIG. 4-FIG 6). Therefore, even if the probe base 20 in the above embodiments is only disposed with the high-frequency metal probe 32 for contacting the DUT, the coupling effect still occurs by the coupling transmission wires disposing adjacent to the corresponding high-frequency transmission wires, and the high-frequency coupled signal still can be obtained in such disposition. Please refer to FIG. 7. FIG. 7 shows a testing device 6 according to a sixth embodiment of the present invention. Similar to the third embodiment of the present invention (FIG. 4), the testing device 6 comprises a plurality of high-frequency transmission wires paired with a plurality of coupling transmission wires, and the adjusting component 19, but omits the coupling metal probes. In this way, the high-frequency coupled signal can be obtained by the capacitive/inductive coupling effect between the high-frequency transmission wire and the coupling transmission wire, and the capacitive/inductive coupling between the coupling circuit and the high-frequency circuit can be adjusted by changing the capacitance and/or inductance of the adjusting component 19.

Additionally, since the capacitive/inductive coupling between the high-frequency metal probe and the coupling metal probe forms the high-pass or band-pass filter, the noises on lower frequencies from other probe sets are filtered out when passing through the high-frequency metal probe and the coupling metal probe. Therefore, each embodiment of the present invention applies not only to single-DUT, but also to multi-DUT, thereby providing greater convenience.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for transmitting a high-frequency signal by a coupling effect, comprising:
receiving a plurality of high-frequency signals by a high-frequency circuit and coupling the high-frequency signals to a coupling circuit by the coupling effect to output a high-frequency coupled signal;
forming one of the high-frequency circuit or the coupling circuit comprising a high-frequency metal probe, and forming one of the high-frequency circuit or the coupling circuit comprising a coupling transmission wire, respectively, wherein when the high-frequency circuit comprises the high-frequency metal probe, the coupling circuit comprises the coupling transmission wire; and when the high-frequency circuit comprises the coupling transmission wire, the coupling circuit comprises the high-frequency metal probe; and
adjusting a filter between the coupling circuit and the high-frequency circuit formed by the coupling effect for adjusting a transmission frequency of the high-frequency coupled signal.

2. The method of claim 1, wherein adjusting the filter between the coupling circuit and the high-frequency circuit formed by the coupling effect for adjusting the transmission frequency of the high-frequency coupled signal comprises:
adjusting a distance between a first coupling metal probe and the high-frequency metal probe for adjusting the transmission frequency of the high-frequency coupled signal;
wherein the first coupling metal probe is configured to be adjacent to the high-frequency metal probe to generate the coupling effect; and
the first coupling metal probe is electrically connected to the coupling transmission wire.

3. The method of claim 2, wherein a circuit substrate is provided, and the circuit substrate comprising an upper surface, a lower surface, and an electrical contact on the upper surface for electrically connecting a tester; the coupling transmission wire electrically connects the first coupling metal probe on the lower surface of the circuit substrate; when the coupling circuit comprises the coupling transmission wire, the coupling circuit further comprises the first coupling metal probe, and the coupling transmission wire outputs the high-frequency coupled signal on the upper surface of the circuit substrate.

4. The method of claim 2, wherein a circuit substrate is provided, and the circuit substrate comprising an upper surface, a lower surface, and an electrical contact on the upper surface for electrically connecting a tester; the coupling transmission wire electrically connects the first coupling metal probe on the lower surface of the circuit substrate; when the high-frequency circuit comprises the coupling transmission wire, the high-frequency circuit further comprises the first coupling metal probe, and the coupling transmission wire receives the high-frequency signal on the upper surface of the circuit substrate.

5. The method of claim 2, wherein adjusting the filter between the coupling circuit and the high-frequency circuit formed by the coupling effect for adjusting the transmission frequency of the high-frequency coupled signal further comprises:
disposing a second coupling metal probe for adjusting the transmission frequency of the high-frequency coupled signal; and
selectively disposing a third coupling metal probe for adjusting the transmission frequency of the high-frequency coupled signal;
wherein the second and the third coupling metal probes are configured adjacent to the high-frequency metal probe to generate the coupling effect, and the second and the third coupling metal probes are electrically connected to the coupling transmission wire.

6. The method of claim 5, wherein the high-frequency metal probe, the first, the second, and the third coupling metal probes pass through a probe base.

7. The method of claim 1, wherein adjusting the filter between the coupling circuit and the high-frequency circuit formed by the coupling effect for adjusting the transmission frequency of the high-frequency coupled signal comprises:
configuring a high-frequency transmission wire to be adjacent to the coupling transmission wire for generating the coupling effect; and
adjusting a length of the high-frequency transmission wire or a distance between the high-frequency transmission wire and the coupling transmission wire for adjusting the transmission frequency of the high-frequency coupled signal;
wherein the high-frequency transmission wire is electrically connected to the high-frequency metal probe.

8. The method of claim 7, wherein a circuit substrate is provided, and the circuit substrate comprises an upper surface, a lower surface, and an electrical contact on the upper surface for electrically connecting a tester; the high-frequency transmission wire electrically connects the high-frequency metal probe on the lower surface of the circuit substrate; when the high-frequency circuit comprises the high-frequency metal probe, the high-frequency circuit further comprises the high-frequency transmission wire, and the coupling transmission wire outputs the high-frequency coupled signal on the upper surface of the circuit substrate.

9. The method of claim 7, wherein a circuit substrate is provided, and the circuit substrate comprises an upper surface, a lower surface, and an electrical contact on the upper surface for electrically connecting a tester; the high-frequency transmission wire electrically connects the high-frequency metal probe on the lower surface of the circuit substrate; when the coupling circuit comprises the high-frequency metal probe, the coupling circuit further comprises the high-frequency transmission wire, and the coupling transmission wire receives the high-frequency signal on the upper surface of the circuit substrate.

10. The method of claim 7, wherein a circuit substrate and a space transformer are provided, the circuit substrate comprises an upper surface, a lower surface, and an electrical contact on the upper surface for electrically connecting a tester; the coupling transmission wire is disposed in the circuit substrate and the space transformer; the space transformer is disposed to the lower surface of the circuit substrate and comprises a top side and a bottom side and the top side is adjacent to the lower surface of the circuit substrate; the high-frequency transmission wire is disposed in the space transformer, and electrically connects the high-frequency metal probe at the bottom side of the space transformer; when the high-frequency circuit comprises the high-frequency metal probe, the high-frequency circuit further comprises the high-frequency transmission wire, and the coupling transmission wire outputs the high-frequency coupled signal on the upper surface of the circuit substrate.

11. The method of claim 7, wherein a circuit substrate and a space transformer are provided, the circuit substrate comprises an upper surface, a lower surface, and an electrical contact on the upper surface for electrically connecting a tester; the coupling transmission wire is disposed in the circuit substrate and the space transformer; the space transformer is disposed to the lower surface of the circuit substrate and comprises a top side and a bottom side and the top side is adjacent to the lower surface of the circuit substrate; the high-frequency transmission wire is disposed in the space transformer, and electrically connects the high-frequency metal probe at the bottom side of the space transformer; when the coupling circuit comprises the high-frequency metal probe, the coupling circuit further comprises the high-frequency transmission wire, and the coupling transmission wire receives the high-frequency signal on the upper surface of the circuit substrate.

12. A high-frequency coupling testing device for testing a device under test (DUT) by a coupling effect, the high-frequency coupling testing device comprising:
a circuit substrate, comprising:
a coupling transmission wire for electrically connecting a tester;
a probe base;
a high-frequency metal probe passing through the probe base for contacting the DUT; and
a first coupling metal probe passing through the probe base for electrically connecting the coupling transmission wire;
wherein the first coupling metal probe is configured adjacent to the high-frequency metal probe to form a filter by the coupling effect, and
when the tester transmits a testing signal to the coupling transmission wire, the testing signal is filtered by the filter to form a high-frequency coupled signal and the high-frequency coupled signal is outputted from the high-frequency metal probe to the DUT for testing.

13. The high-frequency coupling testing device of claim 12, wherein the circuit substrate further comprises:
an electrical contact formed on an upper surface of the circuit substrate for electrically connecting the tester; and
a conductive wire in the circuit substrate for electrically connecting the electrical contact and the coupling transmission wire.

14. The high-frequency coupling testing device of claim 13, further comprising a high-frequency transmission wire;
wherein the high-frequency transmission wire electrically connects the high-frequency metal probe and is configured adjacent to the coupling transmission wire.

15. The high-frequency coupling testing device of claim 13, further comprising:
a locating base in a center of the circuit substrate;
wherein the probe base is disposed at a bottom of the locating base, a first end of the coupling transmission wire is disposed on the upper surface of the circuit substrate and a second end of the coupling transmission wire passes through the locating base and connects the first coupling metal probe at the bottom of the locating base.

16. The high-frequency coupling testing device of claim 12, further comprising:
a second coupling metal probe passing through the probe base; and
a conductive layer for electrically connecting the first and the second coupling metal probes;
wherein the first and the second coupling metal probes are configured adjacent to the high-frequency metal probe to adjust the filter.

17. A high-frequency coupling testing device for testing a DUT by a coupling effect, the high-frequency coupling testing device comprising:
a circuit substrate, comprising:
an upper surface;
a lower surface; and
an electrical contact on the upper surface for electrically connecting a tester;
a high-frequency transmission wire;
a coupling transmission wire, being configured adjacent to the high-frequency transmission wire for forming a filter by the coupling effect; and
a high-frequency metal probe for electrically connecting the high-frequency transmission wire and the DUT;
wherein the coupling transmission wire electrically connects the electrical contact, and
when the tester transmits a testing signal to the coupling transmission wire, the testing signal is filtered by the filter to form a high-frequency coupled signal and the high-frequency coupled signal is outputted from the high-frequency metal probe to the DUT for testing.

18. The high-frequency coupling testing device of claim 17, wherein the circuit substrate further comprises:
a conductive wire in the circuit substrate for electrically connecting the electrical contact and the coupling transmission wire.

19. The high-frequency coupling testing device of claim 18, further comprising:
a locating base in a center of the circuit substrate; and
a probe base at a bottom of the locating base for the high-frequency metal probe to pass through;
wherein a first end of the coupling transmission wire is disposed on the upper surface of the circuit substrate and a second end of the coupling transmission wire passes through the locating base and abuts the bottom of the locating base.

20. The high-frequency coupling testing device of claim 17, further comprising:
a probe base;
a first coupling metal probe adjacent to the high-frequency metal probe;
a second coupling metal probe adjacent to the high-frequency metal probe; and
a conductive layer in the probe base for electrically connecting the first and the second coupling metal probes;
wherein the first and the second coupling metal probes and the high-frequency metal probe pass through the probe base, and
the first coupling metal probe electrically connects the coupling transmission wire.

21. The high-frequency coupling testing device of claim 17, further comprising:
a space transformer on the lower surface of the circuit substrate;
a probe base at a bottom side of the space transformer; and
a coupling metal probe adjacent to the high-frequency metal probe;
wherein the coupling metal probe electrically connects the coupling transmission wire,
the coupling transmission wire comprises a first coupling transmission wire in the circuit substrate and a second coupling transmission wire in the space transformer;
and the high-frequency transmission wire is adjacent to the second coupling transmission wire to adjust the filter.
